(19) United States
(12) Patent Application Publication
(10) Pub. No.: US 2015/0362769 A1
(43) Pub. Date: Dec. 17, 2015

(54) CHIP ON FILM SUBSTRATE, METHOD FOR MANUFACTURING THE SAME AND DISPLAY DEVICE

(71) Applicant: SHENZHEN CHINA STAR OPTOELECTRONICS TECHNOLOGY CO. LTD., Shenzhen, Guangdong (CN)

(72) Inventor: Shishuai HUANG, Guangdong (CN)

(21) Appl. No.: 14/391,060

(22) PCT Filed: Jun. 30, 2014
(86) PCT No.: PCT/CN2014/081089

§ 371 Date: Oct. 7, 2014

(30) Foreign Application Priority Data
Jun. 12, 2014 (CN) 201410260846.9

(51) Int. Cl. G02F 1/1368; H01L 25/065; H01L 23/528; H01L 21/3205; H01L 25/00; H01L 23/31; H01L 23/29; H01L 27/12; H01L 23/532

(52) U.S. Cl. CPC G02F 1/1368; H01L 27/124; H01L 25/0657; H01L 23/528; H01L 23/53228; H01L 25/50; H01L 23/3157; H01L 23/29; H01L 21/32051; G02F 2001/136222

(57) ABSTRACT

A chip-on-film (COF) substrate is provided, comprising: a substrate; bonding leads disposed on a surface of the substrate; a protection layer disposed on a predetermined position of the bonding leads; a metal thin film protective layer disposed on an area of the bonding leads without coating with the protection layer. The time of the corrosion of the copper is delayed and the rate of the corrosion of the copper is slowed down though coating the active metal thin film protective layer on a portion of the bonding leads of the COF substrate exposed to the air, reducing the risk of the bonding lead of the COF substrate being corroded and cracking.

### FIELD OF THE INVENTION

The present invention relates to a technical field of displays, and more particularly, to a chip-on-film (COF) substrate, a method for manufacturing the same and a display panel.

### BACKGROUND OF THE INVENTION

A thin film transistor liquid crystal display (TFT-LCD) panel needs to use a COF substrate to connect a printed circuit board (PCB) and a liquid crystal panel while normal display, so that a signal from the PCB can be conducted to the panel.

Referring to FIG. 1, a bonding lead 2 is disposed on a COF substrate 1 and coated with a protection layer 3. Since the copper has great properties in both electrically conductivity and thermal conductivity, and also has a great flexibility, the copper is often used as a material of which the bonding lead is made. In the COF substrate, a bonding lead preserved from coating of the protection layer 3 is used for soldering to the liquid crystal panel.

In the module stage, a lateral side of the thin film transistor of the liquid crystal panel is coated with a layer made of tuffy resin glue after the COF substrate is soldered, in order to prevent corrosion of the bonding lead of the liquid crystal panel, such as H₂O, ions corrosions. However, a back side of the COF is generally restricted by the process from coating of a tuffy resin glue. As referring to FIG. 2, the bonding lead on the COF is partially exposed to the air. Although the anti-corrosive property of the copper is strong enough to prevent the vapor corrosion, the copper will be corroded through an electrochemical reaction in ionic environment, in particular to the presence of chloride ions. Since chloride ions have a strong penetrability and are readily hydrolyzed to acid, accelerating the following electrochemical reactions to form pitting corrosion in which an aggravated situation further causes the exposed copper breaking to affect the signal transmission. The electrochemical reactions are as follows:

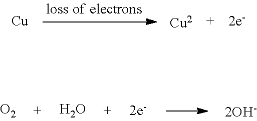

### SUMMARY OF THE INVENTION

An objective of the present invention is to provide a COF substrate, a method for manufacturing the same and a display panel, for solving the problems of the conventional technology in which a portion of the bonding lead on the COF substrate exposed to the air was corroded through an electrochemical reaction in the environment with the ions so that the signal transmission was affected.

The present invention is accomplished by providing a display panel comprising:

a color filter;

an array substrate disposed on the color filter;

terminal traces disposed on the array substrate and electrically connected to bonding leads;

a substrate;

the bonding leads disposed on a surface of the substrate;

a protection layer disposed on an intermediate position of the bonding leads; and

a metal thin film protective layer disposed on where are disconnection of the bonding leads with the terminal traces of the array substrate;

wherein a metal activity of a metal material of the metal thin film protective layer is greater than or equal to a metal activity of a metal material of the bonding leads.

In an embodiment, the metal thin film protective layer is further disposed on where are connection of the bonding leads with the terminal traces of the array substrate.

In an embodiment, a thickness of the metal thin film protective layer is greater than or equal to a thickness of the bonding leads.

In an embodiment, the metal material of the metal thin film protective layer comprises Al, Zn, Fe, or Sn.

In an embodiment, the metal material of the bonding leads is a copper wire.

Another objective of the present invention is to provide a method for manufacturing a COF substrate, the COF substrate transmitting driving signals to an array substrate through terminal traces disposed on the array substrate, the method for manufacturing the COF substrate comprises the following steps of:

providing a substrate in which bonding leads are disposed;

coating a protection layer on a predetermined position of the bonding leads; and

forming a metal thin film protective layer on an area of the bonding leads without coating with the protection layer;

wherein the bonding leads of the COF substrate are connected to the terminal traces of the array substrate, the metal thin film protective layer is disposed on where are disconnection of the bonding leads with the terminal traces of the array substrate.

In an embodiment, the method further comprises the following steps:

forming the metal thin film protective layer on where are connection of the bonding leads with the terminal traces of the array substrate.

In an embodiment, a metal activity of a metal material of the metal thin film protective layer is greater than or equal to a metal activity of a metal material of the bonding leads.

In an embodiment, a thickness of the metal thin film protective layer is greater than or equal to a thickness of the bonding leads.

Another objective of the present invention is to provide a COF substrate, the COF substrate transmitting driving signals to an array substrate through terminal traces disposed on the array substrate, the COF substrate comprising:

a substrate;

bonding leads disposed on a surface of the substrate;

a protection layer disposed on a predetermined position of the bonding leads; and

a metal thin film protective layer disposed on an area of the bonding leads where are uncoated with the protection layer;

wherein the bonding leads of the COF substrate are connected to the terminal traces of the array substrate, the metal thin film protective layer is disposed on where are disconnection of the bonding leads with the terminal traces of the array substrate.

In an embodiment, the metal thin film protective layer is further disposed on where are connection of the bonding leads with the terminal traces of the array substrate.

In an embodiment, a metal activity of a metal material of the metal thin film protective layer is greater than or equal to a metal activity of a metal material of the bonding leads.

In an embodiment, a thickness of the metal thin film protective layer is greater than or equal to a thickness of the bonding leads.

Another objective of the present invention is to provide a display panel, comprising:

a color filter;

an array substrate disposed on the color filter;

terminal traces disposed on the array substrate and electrically connected to bonding leads;

a substrate;

the bonding leads disposed on a surface of the substrate;

a protection layer disposed on an intermediate position of the bonding leads; and

a metal thin film protective layer disposed on where are disconnection of the bonding leads with the terminal traces of the array substrates.

In an embodiment, the metal thin film protective layer is further disposed on where are connection of the bonding leads with the terminal traces of the array substrate.

In the present invention, by coating the active metal thin film protective layer on a portion of the bonding leads of the COF substrate exposed to the air, this does not affect the conductivity and does further protect the bonding leads made of the copper material. The embodiments of the present invention principally utilizes the chemical properties of Al, Zn, Fe or Sn, which are more reactive than that of the copper, to easily lose electrons and generate electrochemical reactions in vaporific and ionic environment. Thus, the time and rate in corrosion of the copper is mitigated and an active metal thin film protective layer is formed on the bonding leads made of the copper material. The embodiments of the present invention sufficiently reduce the risks of the bonding leads of the COF substrate being corroded and cracking, thereby increasing the usage time, and extending the life of the product.

### DESCRIPTION OF THE DRAWINGS

FIG. 1 is a schematic structural view of a conventional COF structure;

FIG. 2 is a schematic structural view of a portion of bonding leads, which is exposed to the air, on the conventional COF substrate;

FIG. 3 is a flowchart of a method for manufacturing a chip-on-film (COF) substrate according to an embodiment of the present invention;

FIG. 4 is a schematic structural view of a portion of the bonding leads disposed with a metal thin film protective layer according to the embodiment of the present invention;

FIG. 5 is a schematic structural view of the metal thin film protective layer disposed on all positions where are uncoated with a protection layer on the bonding leads according to the embodiment of the present invention; and

FIG. 6 is a schematic view of a display panel according to the embodiment of the present invention.

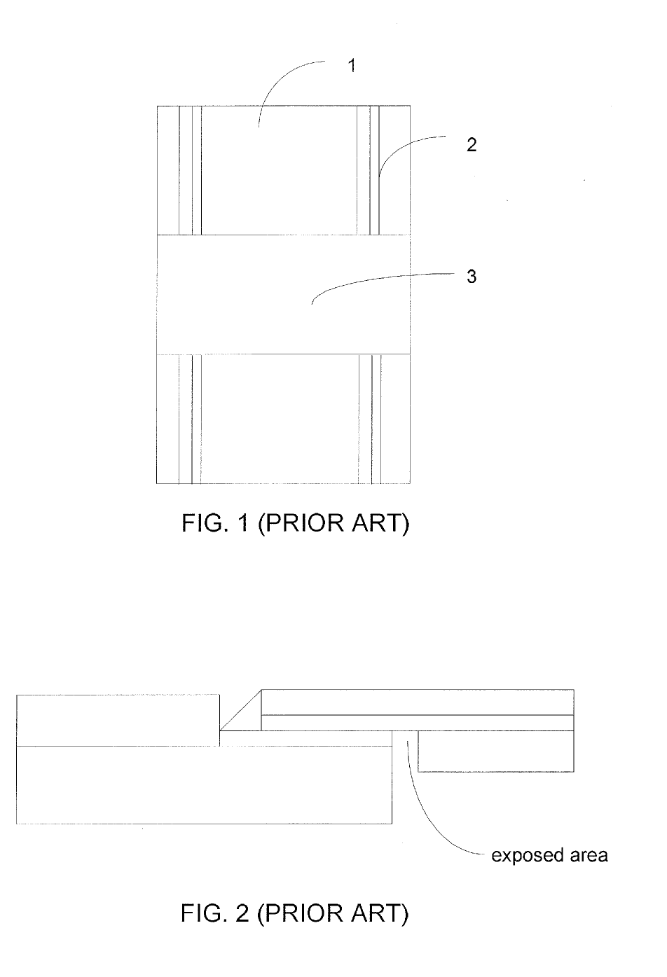

### DETAILED DESCRIPTION OF THE PREFERRED EMBODIMENTS

The following embodiments and drawings are made for the purpose of illustrating the general principles of the present invention and are used to describe and understand the present invention. It is to be understood that the embodiments are of the best-contemplated mode of carrying out the present invention, but it is not limited thereto.

In an embodiment of the present invention, by coating the active metal thin film protective layer on a portion where the bonding leads are exposed to the air on the COF substrate, this will not affect the conductivity and does further protect the bonding leads made of the copper material. The embodiment of the present invention effectively reduces the risks of the bonding leads of the COF substrate being corroded and cracking, thereby solving the prior art's problems that on the COF substrate a portion of the bonding leads exposed to the air will be corroded through an electrochemical reaction in ionic environment, and further negatively influences the signal transmission.

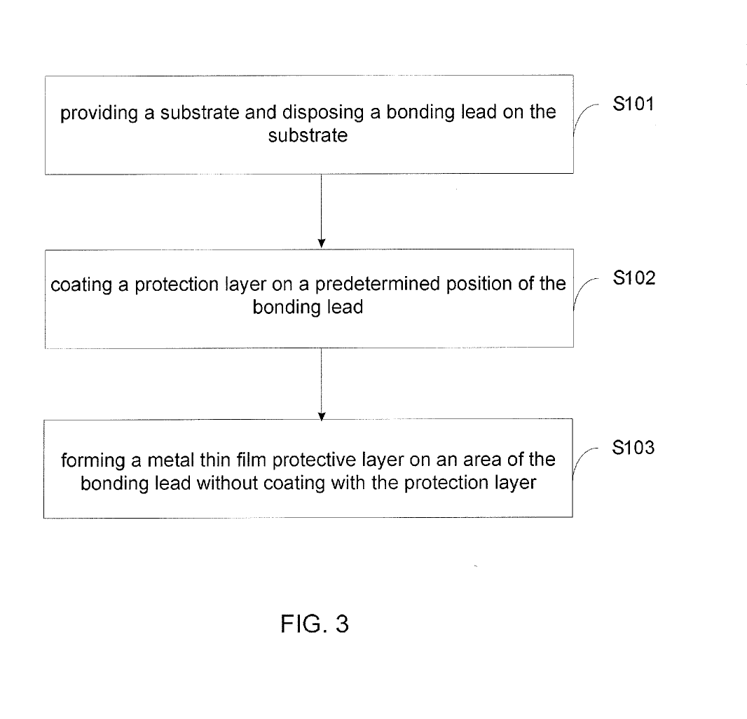

Referring to FIG. 3, the present invention provides a method for manufacturing COF substrate which comprises the following steps of:

In step S101, providing a substrate and disposing bonding leads on the substrate.

In the embodiment of the present invention, a plurality of bonding leads are disposed on the COF substrate and are configured to electrically connect with terminal traces disposed on an array substrate, wherein a material of which the bonding leads is made is a copper.

In step S102, a protection layer is coated on a predetermined position of the bonding leads.

Preferably, the protection layer is coated on an intermediate position of the bonding leads.

In the embodiment of the present invention, while the protection layer is coated on the intermediate position of the bonding leads, both of end positions of the bonding leads do not need to be coated by the protective layer. The objective is that where is uncoated with the protective layer on the bonding leads need to be electrically connected to the terminal traces disposed on the array substrate.

In step S103, a metal thin film protective layer is formed on an area where is uncoated with the protective layer on the bonding leads.

In the embodiment of the present invention, after the bonding leads of the COF substrate are connected to the terminal traces disposed on the array substrate, the metal thin film protective layer disposes on where are disconnections of the bonding leads with the terminal traces disposed on the array substrate, wherein the COF substrate transmit driving signals to the array substrate via the terminal traces disposed on the array substrate.

In the embodiment of the present invention, the area of the bonding leads which are uncoated with the protection layer are coated with the metal thin film protective layer which has a metal activity greater than the copper. The metal material of the metal thin film protective layer having the metal activity greater than the copper comprises Al, Zn, Fe, Sn or other metals having the metal activity greater than the copper.

As an embodiment of the present invention, in order to reduce materials and reduce the production process, the metal thin film protective layer is only formed on where is not coated with the protection layer on the bonding leads and is neighbored to the protection layer.

Preferably, when the bonding leads are connected to the terminal traces disposed on an array substrate, the metal thin film protective layer is disposed on where is exposed to the air on the bonding leads. That is, after the bonding leads of the COF substrate are connected to the terminal traces disposed on the array substrate, the metal thin film protective layer is disposed on the where are disconnections of the bonding leads with the terminal traces disposed on the array substrate.

As another embodiment of the present invention, to greatly reduce the risks of the bonding leads being corroded and cracking, the metal thin film protective layer is formed on all of the positions where are uncoated with the protection layer on the bonding leads. Namely, the metal thin film protective layer is formed on where are uncoated with the protection layer on the bonding leads connected to the terminal traces of the array substrate.

Preferably, to greatly reduce the risks of the bonding leads being corroded and cracking, a thickness of the metal thin film protective layer is greater than or equal to a thickness of the bonding leads. This can mitigate copper corrosion in both time and rate thereof. However, it should be understood that the thickness of the metal thin film protective layer can be adjusted according to actual requirements.

In the embodiment of the present invention, after the step S103, the method further comprises the following steps of:

soldering the bonding leads of the COF substrate with the terminal traces of the array substrate so that the bonding leads of the COF substrate are electrically connected to the terminal traces of the array substrate.

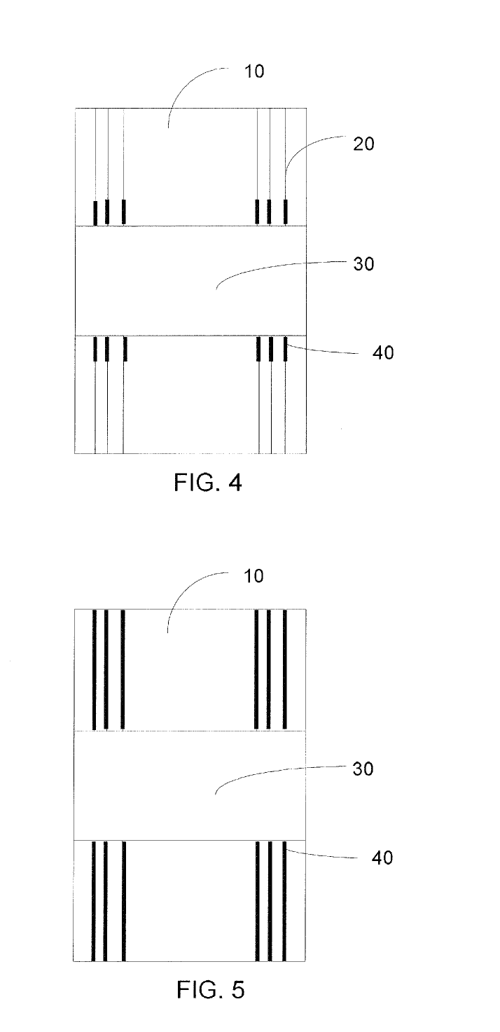

FIG. 4 and FIG. 5 are schematic structural views of a COF substrate according to the embodiment of the present invention. For convenience of description, FIG. 4 and FIG. 5 only show portions related to the embodiment of the present invention. The COF substrate comprises:

a substrate 10;

bonding leads 20 disposed on a surface of the substrate 10;

a protection layer 30 disposed on a predetermined position of the bonding leads 20; and

a metal thin film protective layer 40 disposed on an area of the bonding leads 20 where are uncoated with the protection layer 30.

In the embodiment of the present invention, after the bonding leads 20 of the COF substrate are connected to the terminal traces of the array substrate, the metal thin film protective layer 40 disposed on where are disconnections of the bonding leads 20 with the terminal traces of the array substrate. In addition, the terminal traces through which driving signals are being sent to the array substrate are disposed on the array substrate.

In the embodiment of the present invention, the substrate 10 is a COF substrate where the plurality of bonding leads 20 are disposed. A metal material of the bonding leads 20 is a copper wire. The bonding leads are electrically connected to the terminal traces disposed on the array substrate.

In the embodiment of the present invention, the metal thin film protective layer 40 has a metal activity greater than the copper. A metal material of the metal thin film protective layer having the metal activity greater than the copper comprises Al, Zn, Fe, Sn or other metals having the metal activity greater than the copper.

As an embodiment of the present invention, to save materials and reduce the production process, the metal thin film protective layer 40 is only formed on where are not coated with the protection layer on the bonding leads and are neighbored to the protection layer, as shown in FIG. 4.

Preferably, when the bonding leads 20 are connected to the terminal traces disposed on the array substrate, the metal thin film protective layer 40 is disposed on where are exposed to the air on the bonding leads 20. Namely, after the bonding leads 20 of the COF substrate are connected to the terminal traces disposed on the array substrate, the metal thin film protective layer 40 is disposed on where are disconnections of the bonding leads 20 with the terminal traces disposed on the array substrate.

As another embodiment of the present invention, to greatly reduce the risks of the bonding leads 20 being corroded and cracking, the metal thin film protective layer 40 is disposed on all of positions where are uncoated with the protection layer on the bonding leads, as shown in FIG. 5. Namely, the metal thin film protective layer 40 is formed on where are uncoated with the protection layer on the bonding leads 20 connected with the terminal traces of the array substrate.

Preferably, to greatly reduce the risks of the bonding leads being corroded and cracking, a thickness of the metal thin film protective layer 40 is greater than or equal to a thickness of the bonding leads. This can mitigate the copper corrosion in both of the time and the rate thereof. However, it should be understood that the thickness of the metal thin film protective layer can be adjusted according to actual requirements.

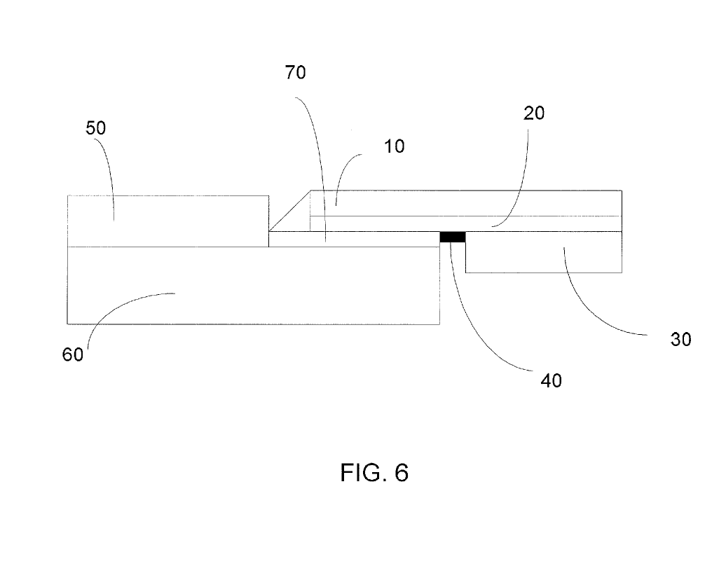

FIG. 6 is a schematic view of a display panel according to the embodiment of the present invention. For convenience of description, FIG. 6 only shows portions related to the embodiment of the present invention. The COF substrate comprises: a substrate 10, bonding leads 20, a protection layer 30, a metal thin film protective layer 40, a color filter 50, an array substrate 60 and a terminal traces 70.

The bonding leads 20 are disposed on a surface of the substrate, and the protection layer 30 is disposed on a predetermined position of the bonding leads 20. Preferably, the protection layer 30 is disposed on an intermediate position of the bonding leads 20. The metal thin film protective layer 40 is disposed on where are disconnections of the bonding leads 20 with the terminal traces of the array substrate. The array substrate 60 is disposed on the color filter 50. The terminal traces 70 are disposed on the array substrate 60 and are electrically connected to the bonding leads 20.

In the embodiment of the present invention, the substrate 10 is a COF substrate where a plurality of bonding leads 20 are disposed. A metal material of the bonding leads 20 is a copper wire. The bonding leads 20 are electrically connected to the terminal traces 70 disposed on the array substrate 60, wherein the COF substrate transmits driving signals to the array substrate 60 through terminal traces 70 disposed on the array substrate 60.

In the embodiment of the present invention, the metal thin film protective layer 40 has a metal activity greater than the copper. A metal material of the metal thin film protective layer having the metal activity greater than the copper comprises Al, Zn, Fe, Sn or other metals having the metal activity greater than the copper.

As an embodiment of the present invention, to save materials and reduce the production process, the metal thin film protective layer 40 is only formed on where are not coated with the protection layer on the bonding leads and are neighbored to the protection layer, as shown in FIG. 4.

Preferably, when the bonding leads 20 are connected to the terminal traces 70 disposed on the array substrate 60, the metal thin film protective layer 40 is disposed on where are exposed to the air on the bonding leads 20. Namely, after the bonding leads 20 of the COF substrate are connected to the terminal traces 70 disposed on the array substrate, the metal thin film protective layer 40 is disposed on where are disconnections of the bonding leads 20 with the terminal traces 70 disposed on the array substrate 60.

As another embodiment of the present invention, to greatly reduce the risks of the bonding leads 20 being corroded and cracking, the metal thin film protective layer 40 is disposed on all of the positions where are uncoated with the protection layer on the bonding leads, as shown in FIG. 5. Namely, the metal thin film protective layer 40 is coated on where are uncoated with the protection layer 30 on the bonding leads 20 connected with the terminal traces 70 disposed on the array substrate 60.

Preferably, to greatly reduce the risks of the bonding lead being corroded and cracking, a thickness of the metal thin film protective layer 40 is greater than or equal to a thickness of the bonding leads. This can mitigate the copper corrosion in both the time and the rate thereof. However, it should be understood that the thickness of the metal thin film protective layer can be adjusted according to actual requirements.

As described above, by coating the active metal thin film protective layer on a portion of the bonding leads exposed to the air on the COF substrate, this does not affect the conductivity and does further protect the bonding leads made of the copper material. The embodiments of the present invention mainly use the chemical properties of Al, Zn, Fe or Sn, which are more reactive than the chemical properties of the copper, to easily lose electrons and generate electrochemical reactions in vaporific and ionic environment. Thus, the copper corrosion in both the time and the rate thereof can be mitigated through coating the active metal thin film protective layer on the bonding lead made of the copper material. The embodiments of the present invention reduce the risks of the bonding leads of the COF substrate being corroded and cracking, thereby increasing the usage time, and extending the life of the product.

The embodiments are chosen and described in order to best explain the principles of the present invention, it is to be understood that the present invention is not limited thereto. Any modifications, equivalent replacements, and variations will be included within the scope of the present invention.

What is claimed is:

1. A display panel, comprising:
a color filter;
an array substrate disposed on the color filter;
terminal traces disposed on the array substrate and electrically connected to bonding leads;
a substrate;
the bonding leads disposed on a surface of the substrate;
a protection layer disposed on an intermediate position of the bonding leads; and
a metal thin film protective layer disposed on where are disconnection of the bonding leads with the terminal traces of the array substrate;
wherein a metal activity of a metal material of the metal thin film protective layer is greater than or equal to a metal activity of a metal material of the bonding lead.

2. The display panel according to claim 1, wherein the metal thin film protective layer is further disposed on where are connection of the bonding leads with the terminal traces of the array substrate.

3. The display panel according to claim 1, wherein a thickness of the metal thin film protective layer is greater than or equal to a thickness of the bonding leads.

4. The display panel according to claim 1, wherein the metal material of the metal thin film protective layer comprises Al, Zn, Fe, or Sn.

5. The display panel according to claim 1, wherein the metal material of the bonding leads is a copper wire.

6. A method for manufacturing a chip-on-film (COF) substrate, the COF substrate transmitting driving signals to an array substrate through terminal traces disposed on the array substrate, the method for manufacturing the COF substrate comprising the following steps of:
providing a substrate where the bonding leads are disposed;
coating a protection layer on a predetermined position of the bonding leads; and
forming a metal thin film protective layer on where are uncoated with the protection layer on the bonding leads;
wherein the bonding leads of the COF substrate are connected to the terminal traces of the array substrate, the metal thin film protective layer is disposed on where are disconnection of the bonding leads with the terminal traces of the array substrate.

7. The method for manufacturing the COF substrate according to claim 6, further comprising the following steps of:
forming the metal thin film protective layer on where are connection of the bonding leads with the terminal traces of the array substrate.

8. The method for manufacturing the COF substrate according to claim 6, wherein a metal activity of a metal material of the metal thin film protective layer is greater than or equal to a metal activity of a metal material of the bonding leads.

9. The method for manufacturing the COF substrate according to claim 6, wherein a thickness of the metal thin film protective layer is greater than or equal to a thickness of the bonding leads.

10. The method for manufacturing the COF substrate according to claim 6, wherein the metal material of the metal thin film protective layer comprises Al, Zn, Fe or Sn.

11. The method for manufacturing the COF substrate according to claim 6, wherein the metal material of the bonding leads is copper wire.

12. A COF substrate, the COF substrate transmitting driving signals to an array substrate through terminal traces disposed on the array substrate, the COF substrate comprising:
a substrate;
bonding leads disposed on a surface of the substrate;
a protection layer disposed on a predetermined position of the bonding leads; and
a metal thin film protective layer disposed on an area of the bonding leads without coating with the protection layer;
wherein the bonding leads of the COF substrate are connected to the terminal traces of the array substrate, the metal thin film protective layer is disposed on where are disconnection of the bonding leads with the terminal traces of the array substrate.

13. The COF substrate according to claim 12, wherein the metal thin film protective layer is further disposed on where are connection of the bonding leads with the terminal traces of the array substrate.

14. The COF substrate according to claim 12, wherein a metal activity of a metal material of the metal thin film protective layer is greater than or equal to a metal activity of a metal material of the bonding leads.

15. The COF substrate according to claim 12, wherein a thickness of the metal thin film protective layer is greater than or equal to a thickness of the bonding leads.

16. A display panel, comprising:
a color filter;
an array substrate disposed on the color filter;
terminal traces disposed on the array substrate and electrically connected to the bonding leads;
a substrate;
the bonding leads disposed on a surface of the substrate;
a protection layer disposed on an intermediate position of the bonding leads; and
a metal thin film protective layer disposed on where are disconnection of the bonding leads with the terminal traces of the array substrate.

17. The display panel according to claim 16, wherein the metal thin film protective layer is further disposed on where are connection of the bonding leads with the terminal traces of the array substrate.

18. The display panel according to claim 16, wherein a thickness of the metal thin film protective layer is greater than or equal to a thickness of the bonding leads.

19. The display panel according to claim 16, wherein a metal material of the metal thin film protective layer comprises Al, Zn, Fe, or Sn.

20. The display panel according to claim 16, wherein a metal material of the bonding leads is a copper wire.
